(19) United States
(12) Patent Application Publication
(10) Pub. No.: US 2008/0237855 A1
(43) Pub. Date: Oct. 2, 2008

(54) Ball grid array package and its substrate

(75) Inventors: Wen-Jeng Fan, Hsinchu (TW); Tsai-Chuan Yu, Hsinchu (TW)

Correspondence Address: TROXELL LAW OFFICE PLLC, SUITE 1404, 5205 LEESBURG PIKE, FALLS CHURCH, VA, 22041, US

(73) Assignee: POWERTECH TECHNOLOGY INC.

(21) Appl. No.: 11/727,902

(22) Filed: Mar. 28, 2007

(51) Int. Cl. H01L 23/488

(52) U.S. Cl. 257/738; 257/E23.023

(57) ABSTRACT

A BGA package and a substrate for the package are disclosed. A chip is disposed on a top surface of the substrate. A plurality of solder balls are disposed on a plurality of ball pads formed on a bottom surface of the substrate. The substrate has at least a core layer with a plurality of corner cavities filled with low-modulus materials as stress buffer. Additionally, some of the ball pads at the corners of the substrate are disposed under the corner cavities.

### FIELD OF THE INVENTION

The present invention relates to an IC package, and more particularly to a Ball Grid Array (BGA) package and its substrate.

### BACKGROUND OF THE INVENTION

Ball Grid Array packages, BGA, have become popular IC packages using a plurality of solder balls to solder onto an external Printed Circuit Board, PCB. When a BGA package is surface-mounted on a PCB, a thermal cycle test is performed for reliability test. Thermal stresses would concentrate on some specific solder balls, especially at the corners of the substrate and under the corners of an encapsulated chip, causing breaking at the solder joints due to the differences of Coefficient of Thermal Expansion, CTE, between BGA and PCB. The similar result is observed during a drop test.

As shown in FIG. 1 and FIG. 2, a conventional BGA package 100 primarily comprises a substrate 110, a chip 120, a plurality of solder balls 130 and an encapsulant 150. The substrate 110 has a top surface 111, a bottom surface 112 and a plurality of ball pads 113, where the ball pads 113 are formed on the bottom surface 112. A die-attaching area 114 is defined on the top surface 111 of the substrate 110 where the active surface of the chip 120 is attached to the die-attaching area 114 of the top surface 111 of the substrate 110 by a die-attaching layer 160. The chip 120 is electrically connected to the substrate 110 by a plurality of bonding wires 140 where the substrate 110 has a wire-bonding slot 115 for passing through the bonding wires 140. The solder balls 130 are disposed on the ball pads 113 for electrical connection to an external PCB 10. The chip 120 and the bonding wires 140 are encapsulated by the encapsulant 150. As specifically shown in FIG. 1, when the BGA package 100 is surface-mounted on the PCB 10, thermal stresses will concentrate at several of the solder balls 130 disposed adjacent to some ball pads 113A at the corners of the substrate 110 or under the corners of the chip 120 causing breaks 116 at the solder balls 130 and leading to electrical open.

### SUMMARY OF THE INVENTION

The main purpose of the present invention is to provide a BGA package and its substrate by creating corner cavities filled with low-modulus materials at the corners of the substrate to be stress buffers which can adsorb thermal stresses and avoid cracks in the solder balls at the corners of the substrate.

The second purpose of the present invention is to provide a BGA package and its substrate to avoid the stresses from the corners of the chip directly transferring to the corresponding solder balls and ball pads under the corners of the chip.

According to the present invention, a BGA package mainly comprises a substrate, a chip, and a plurality of solder balls. The substrate has a top surface and a bottom surface where a plurality of ball pads are formed on the bottom surface. The chip is attached to the top surface of the substrate and is electrically connected to the substrate. The solder balls are disposed on the ball pads. The substrate includes at least a core layer between the top surface and the bottom surface, where the core layer has a plurality of corner cavities filled with low-modulus materials, moreover, some of the ball pads at the corners of the substrate are disposed under the corner cavities. In different embodiments, the corner cavities filled with low-modulus materials at the corners of the substrate can be replaced by a plurality of stress buffering components.

### DESCRIPTION OF THE DRAWINGS

FIG. 1 shows a cross-sectional view of a conventional BGA package.

FIG. 2 shows a bottom view of the conventional BGA package.

FIG. 3 shows a cross-sectional view of a BGA package according to the first embodiment of the present invention.

FIG. 4 shows a bottom view of the BGA package according to the first embodiment of the present invention.

FIG. 5 shows a top view of the substrate of the BGA package according to the first embodiment of the present invention.

FIG. 6A to 6E show cross-sectional views of the substrate during manufacturing processes according to the first embodiment of the present invention.

FIG. 7 shows a cross-sectional view of a BGA package according to the second embodiment of the present invention.

FIG. 8 shows a top view of the substrate of the BGA package according to the second embodiment of the present invention.

FIG. 9A to 9D show cross-sectional views of the substrate during manufacturing processes according to the second embodiment of the present invention.

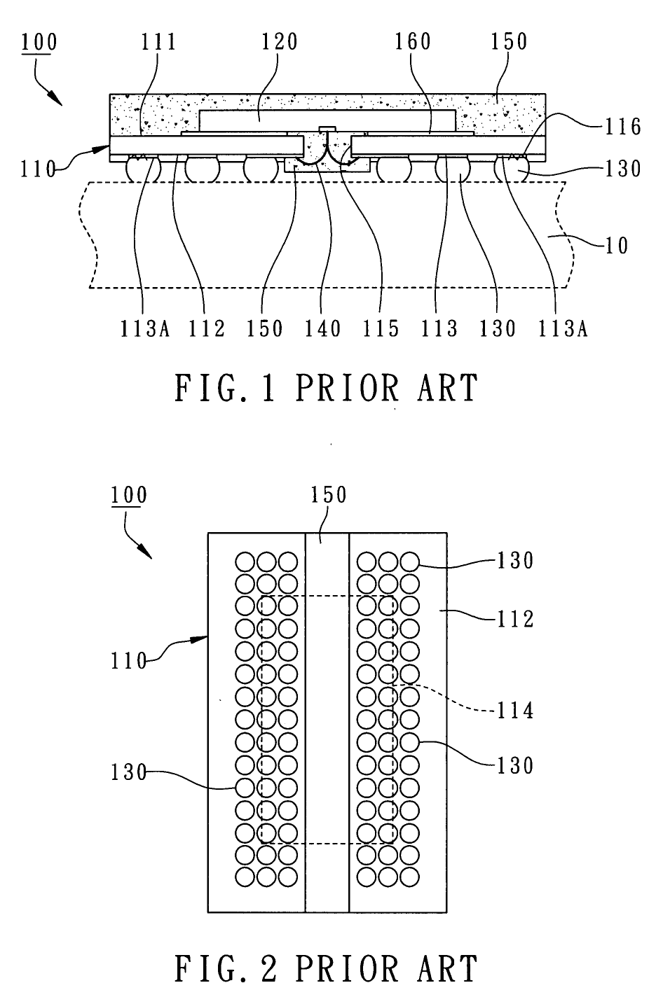

### DETAIL DESCRIPTION OF THE INVENTION

Please refer to the attached drawings, the present invention will be described by means of embodiment(s) below.

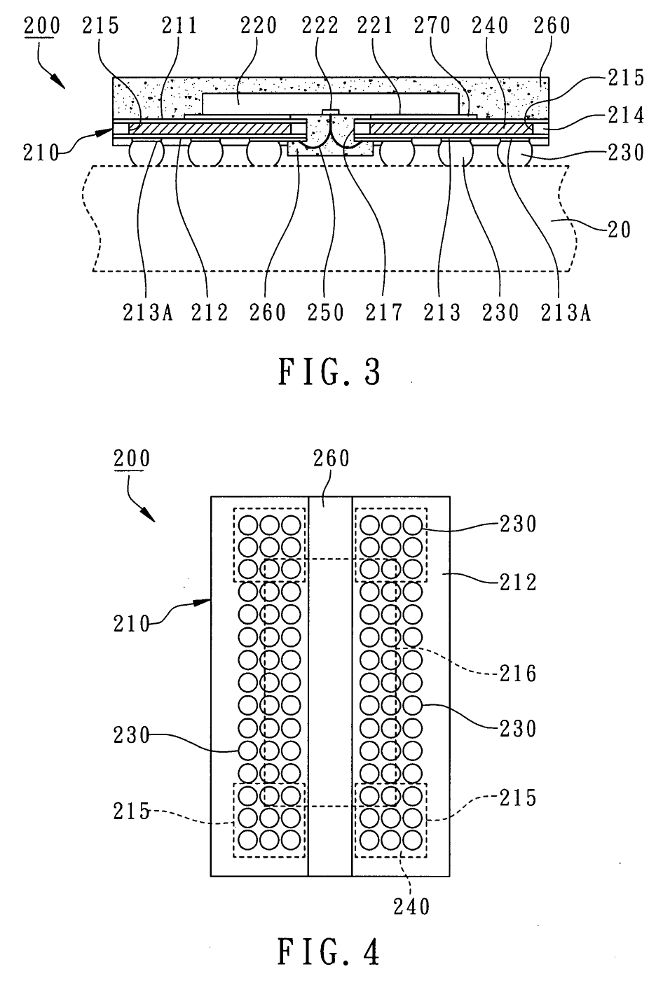

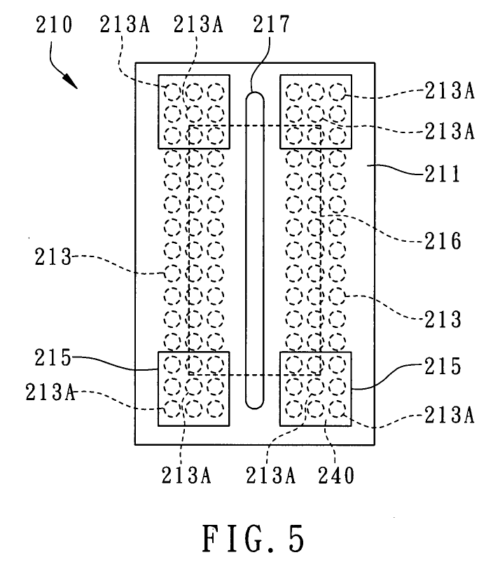

According to the first embodiment of the present invention, as shown in FIG. 3 and FIG. 4, a BGA package 200 mainly comprises a substrate 210, a chip 220, and a plurality of solder balls 230. The substrate 210 has a top surface 211 and a bottom surface 212 where a plurality of ball pads 213 are formed on the bottom surface 212, a die-attaching area 216 is defined on the top surface 211 for attaching the chip 220. Moreover, as shown in FIG. 5, some of the ball pads 213 at the corners of the substrate 210 or/and at the corners of the die-attaching area 216 are defined as ball pads 213A bearing the most intense thermal stresses.

The chip 220 is disposed on the top surface 211 of the substrate 210 and is electrically connected to the substrate 210. In the present embodiment, the active surface 221 of the chip 220 is attached to the top surface 211 of the substrate 210 by a die-attaching layer 270 aligned with the die-attaching area 216. As shown in FIG. 3, the substrate may have a wire-bonding slot 217 crossing the die-attaching area 216, moreover, the BGA package 200 further has a plurality of bonding wires 250 passing through the wire-bonding slot 217 to electrically connect the bonding pads 222 of the chip 220 to the substrate 210.

The solder balls 230 are disposed on the ball pads 213 for surface mounting the BGA package 200 to an external PCB 20, as shown in FIG. 3.

As shown in FIG. 3, FIG. 4, and FIG. 5 again, the substrate 210 includes at least a core layer 214 where the core layer 214 has a plurality of corner cavities 215 filled with low-modulus materials 240 such as rubber, silicone gel, or resin to be embedded stress buffers. Furthermore, the ball pads 213A at the corners of the substrate 210 are disposed under the corner cavities 215. The corner cavities 215 are rectangular and are not extended to the edges of the substrate 210 to avoid the low-modulus materials 240 exposed from the edges of the BGA package 200 and to have a better moisture resistance. Preferably, as shown in FIG. 5, the four corners of the die-attaching area 216 defined on the top surface 211 of the substrate 210 are overlapped on the corner cavities 215 so that the stresses induced by the corners of the chip 220 on the substrate 210 can be dispersed and absorbed by the low-modulus materials 240 without transferring the stresses to the solder balls 230 and the corresponding ball pads 213A under the corners of the chip 220.

Furthermore, the BGA package 200 further has an encapsulant 260 formed on the top surface 211 of the substrate 210 to encapsulate at least a portion of the chip 220, such as only the sidewalls of the chip 220 or the entire chip 220. In the present embodiment, the encapsulant 260 is also formed inside the wire-bonding slot 217 to encapsulate the bonding wires 250. Normally, the Young's modulus of the encapsulant 260 is higher than the one of the low-modulus materials 240.

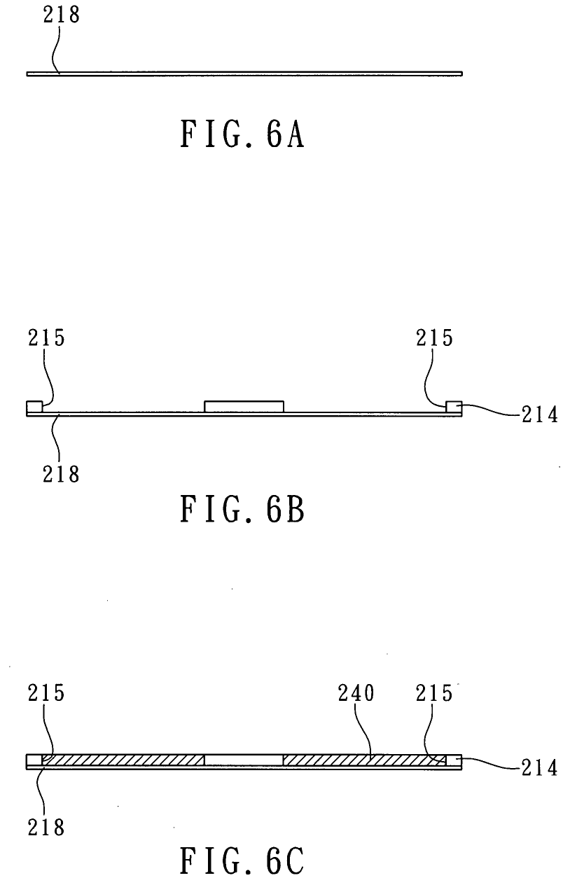

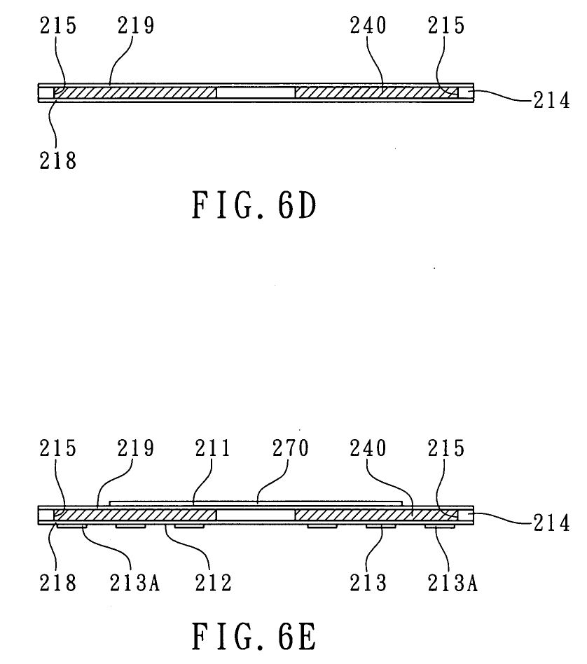

The manufacturing processes of the substrate 210 are described in detail from FIG. 6A to FIG. 6E. Firstly, as shown in FIG. 6A, a core layer 218 is provided for the substrate 210. Then, as shown in FIG. 6B, another core layer 214 is laminated on the core layer 218 and a plurality of corner cavities 215 are created from the core layer 214. Then, as shown in FIG. 6C, low-modulus materials 240 are filled in the corner cavities 215. Then, as shown in FIG. 6D, another core layer 219 is laminated on the patterned core layer 214 to embed and to completely encapsulate the low-modulus materials 240 among the core layer 214, 218, and 219, i.e., the low-modulus materials 240 are embedded between the top surface 211 and the bottom surface 212 of the substrate 210 as shown in FIG. 6E. Finally, as shown in FIG. 6E, the ball pads 213 including the ball pads 213A with the corresponding traces are created on the core layer 218. A die-attaching layer 270 can be pre-disposed on the core layer 219 for attaching the chip 220, as shown in FIG. 3.

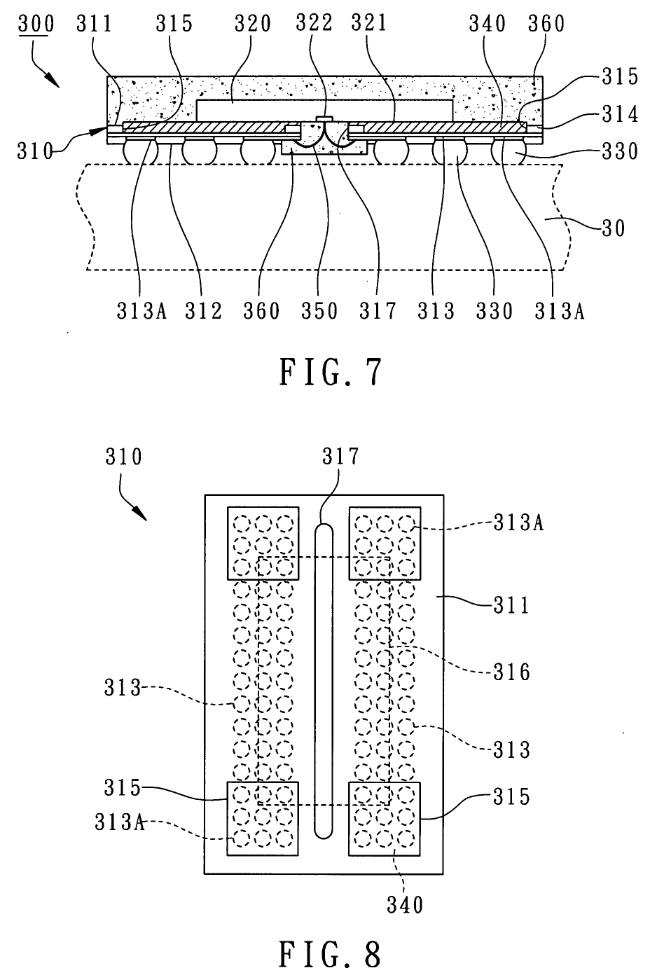

In the second embodiment, another BGA package is revealed in FIG. 7 and FIG. 8. The BGA package 300 primarily comprises a substrate 310, a chip 320, and a plurality of solder balls 330. The substrate 310 has a top surface 311 and a bottom surface 212 where a plurality of ball pads 313 are formed on the bottom surface 312. A die-attaching area 316 is defined on the top surface 311.

A chip 320 is attached to the die-attaching area 316 on the top surface 311 of the substrate 310 and is electrically connected to the substrate 310. In the present embodiment, the active surface 321 of the chip 320 is attached to the top surface 311 of the substrate 310. The solder balls 330 are disposed on the ball pads 313 to electrically connect the BGA package 330 to an external PCB 30 (as shown in FIG. 7) where the PCB 30 can be mother boards for electronic products or cellular phones or modular boards for memory devices.

The BGA package 300 further includes a plurality of bonding wires 350 to electrically connect the bonding pads 322 of the chip 320 to the substrate 310 where the substrate 310 has a wire-bonding slot 317 for passing through the bonding wires 350. In the present embodiment, the BGA package 300 further has an encapsulant 360 to encapsulate the chip 320. Moreover, the encapsulant 360 can be formed inside the wire-bonding slot 317 to encapsulate the bonding wires 350.

The substrate 310 includes at least a core layer 314 embedded with a plurality of low-modulus materials 340 as embedded stress buffers so that some of the ball pads 313, especially the ball pads 313A located at the corners of the substrate 310 where stresses are most concentrated, can be disposed under the low-modulus materials 340. The low-modulus materials 340 can be formed in sections on the substrate 310 by printing. The low-modulus materials 340 can also be individually preformed as stress buffers such as elastic elements and be disposed in the corner cavities 315 of the core layer 314. In the present embodiment, the thicknesses of the low-modulus materials 314 or the elastic elements are thicker than the core layer 314 such that the low-modulus materials 314 are exposed from the top surface 311. Preferably, the corners of the die-attaching area 316 of the substrate 310 are overlapped on the low-modulus materials 340. Accordingly, the corners of the chip 320 contact the low-modulus materials 314 for stress dispersion in the substrate 310. Preferably, the low-modulus materials 314 are adhesive so that the contact with the chip 320 is direct.

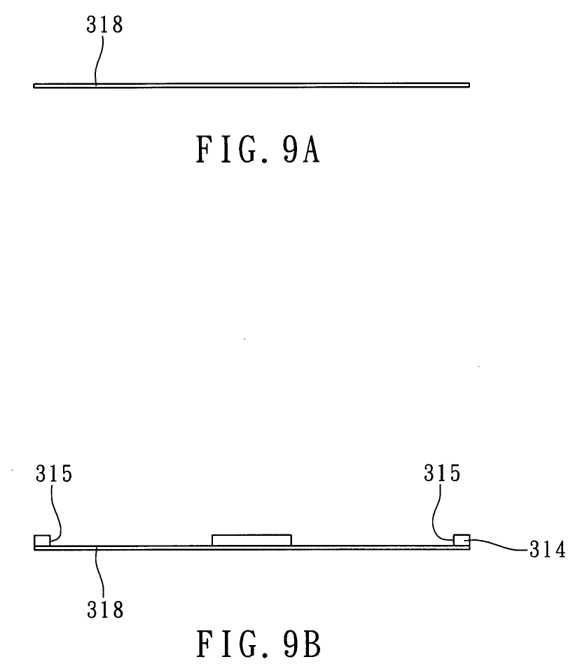

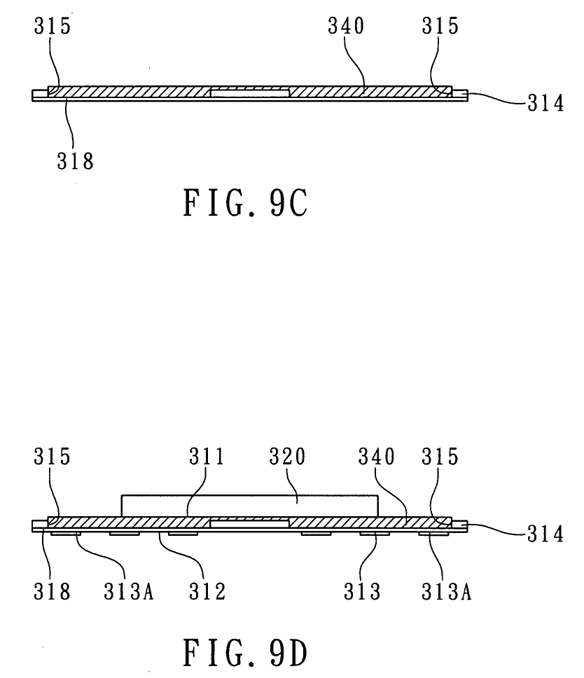

The manufacturing processes of the substrate 310 are described in detail from FIG. 9A to 9D. Firstly, as shown in FIG. 9A, a core layer 318 or a copper foil is provided for the substrate 310. Then, as shown in FIG. 9B, another core layer 314 is laminated on the core layer 318 and a plurality of corner cavities 315 are created from the core layer 318. Then, as shown in FIG. 9C, low-modulus materials 340 are filled in the corner cavities 315 by plug-in, dispensing or printing, where the thickness of the low-modulus materials 340 is thicker than the one of the core layer 314. Finally, as shown in FIG. 9D, the ball pads 313 including the ball pads 313A located at the corners of the substrate 310 and the corresponding traces are disposed at the bottom surface of the core layer 318 or etching the copper foil to form the ball pads 313. In the present embodiment, the low-modulus materials 340 can be used as a die-attaching material to attach the chip 320.

The above description of embodiments of this invention is intended to be illustrative and not limiting. Other embodiments of this invention will be obvious to those skilled in the art in view of the above disclosure.

What is claimed is:

1. A BGA package comprising:
a substrate having a top surface, a bottom surface, a plurality of ball pads formed on the bottom surface and at least a core layer between the top surface and the bottom surface;
a chip disposed on the top surface of the substrate and electrically connected to the substrate; and
a plurality of solder balls disposed on the ball pads;
wherein the core layer has a plurality of corner cavities filled with low-modulus materials, and some of the ball pads at the corners of the substrate are disposed under the corner cavities.

2. The BGA package of claim 1, wherein the corner cavities are rectangular.

3. The BGA package of claim 1, wherein the chip is attached to a die-attaching area on the top surface of the substrate, the die-attaching area having a plurality of corners overlapped on the corner cavities.

4. The BGA package of claim 1, wherein the low-modulus materials are embedded between the top surface and the bottom surface of the substrate.

5. The BGA package of claim 3, wherein the low-modulus materials are exposed on the top surface and contacted the corners of the chip.

6. The BGA package of claim 1, further comprising a plurality of bonding wires electrically connecting the chip to the substrate.

7. The BGA package of claim 6, further comprising an encapsulant encapsulating at least a portion of the chip and the bonding wires.

8. A substrate for BGA packages, having a top surface and a bottom surface and comprising:
at least a core layer between the top surface and the bottom surface; and
a plurality of ball pads formed on the bottom surface;
wherein the core layer has a plurality of corner cavities filled with low-modulus materials, and some of the ball pads at the corners of the substrate are disposed under the corner cavities.

9. The substrate of claim 8, wherein the corner cavities are rectangular.

10. The substrate of claim 8, wherein the top surface of the substrate includes a die-attaching area having a plurality of corners overlapped on the corner cavities.

11. The substrate of claim 8, wherein the low-modulus materials are embedded between the top surface and the bottom surface of the substrate.

12. The substrate of claim 8, wherein the low-modulus materials are exposed on the top surface for contacting a plurality of corners of a chip.

13. A BGA package comprising:
a substrate having a top surface, a bottom surface, a plurality of ball pads formed on the bottom surface, and at least a core layer between the top surface and the bottom surface;
a chip disposed on the top surface of the substrate and electrically connected to the substrate;
a plurality of solder balls disposed on the ball pads; and
a stress buffer patterned and embedded in the core layer;
wherein at least one of the ball pads bearing the most concentrated stress is disposed under the stress buffer.

14. The BGA package of claim 13, wherein the stress buffer is an elastic rectangular block.

15. The BGA package of claim 13, wherein the chip is attached to a die-attaching area on the top surface of the substrate, the die-attaching area having a plurality of corners overlapped on the stress buffer.

16. The BGA package of claim 13, further comprising a plurality of bonding wires electrically connecting the chip to the substrate.

17. The BGA package of claim 16, further comprising an encapsulant encapsulating at least a portion of the chip and the bonding wires.

18. A substrate for BGA packages, having a top surface and a bottom surface and comprising:
at least a core layer between the top surface and the bottom surface; and
a plurality of ball pads formed on the bottom surface; and
a stress buffer patterned and embedded in the core layer;
wherein at least one of the ball pads bearing the most concentrated stress is disposed under the stress buffer.

19. The substrate of claim 18, wherein the stress buffer is an elastic rectangular block.

20. The substrate of claim 18, wherein the top surface of the substrate includes a die-attaching area having a plurality of corners overlapped on the stress buffer.
